(19) United States
(12) Patent Application Publication
(10) Pub. No.: US 2016/0155614 A1
(43) Pub. Date: Jun. 2, 2016

(54) SUPPORT UNIT AND SUBSTRATE TREATING APPARATUS INCLUDING THE SAME

(71) Applicant: Semes Co., Ltd., Cheonan-si (KR)

(72) Inventors: Young Jun KIM, Seoul (KR); Won Haeng LEE, Cheonan-si (KR)

(21) Appl. No.: 14/938,004

(22) Filed: Nov. 11, 2015

(30) Foreign Application Priority Data
Nov. 28, 2014 (KR) 10-2014-0169068

(51) Int. Cl. H01J 37/32

(52) U.S. Cl. CPC H01J 37/3244; H01J 37/32715; H01J 37/32532

(57) ABSTRACT

Disclosed is a substrate treating apparatus. The substrate treating apparatus includes a process chamber having a treating space therein, a support unit placed in the process chamber and supporting a substrate, a gas supply unit supplying a treating gas into the process chamber, a plasma source generating plasma using the treating gas, and a liner unit adjacent to or being in contact with an inner side wall of the process chamber or the support unit in the process chamber. The support unit includes an upper plate on which the substrate is placed, a top surface of the upper plate being formed of a non-conduction material, an electrode plate placed below the upper plate and formed of a conduction material, and a lower plate placed below the electrode plate and having a ring shape. A cooling member is provided in the lower plate.

### CROSS-REFERENCE TO RELATED APPLICATIONS

A claim for priority under 35 U.S.C. §119 is made to Korean Patent Application No. 10-2014-0169068 filed Nov. 28, 2014, in the Korean Intellectual Property Office, the entire contents of which are hereby incorporated by reference.

### BACKGROUND

Embodiments of the inventive concepts described herein relate to a substrate treating apparatus for treating a substrate, and more particularly, relate to a substrate treating apparatus using plasma.

The plasma is generated by a greatly high temperature, a strong electric field or RF electromagnetic fields and refers to an ionized gas state consisting of ions, electrons, radical, and the like. A semiconductor device manufacturing process uses the plasma for an etching process. The etching process is carried out by making ion particles contained in the plasma collide with the substrate.

The etching process is performed in a process chamber. The process gas is provided in the process chamber and is excited into the plasma state by supplying a high-frequency power into the process chamber.

A power is supplied to the substrate treating apparatus to generate the plasma. A RF power is used as the power. The RF power which is used to improve efficiency at the substrate treating process needs high bias power RF. However, a temperature in the chamber increases due to a high power occurring in applying the high bias power RF. In particular, a temperature of a liner in the chamber is not controlled, and thus the temperature may increase above a constant temperature. In addition, parts below the support member for supporting the substrate are damaged due to the increase in the temperature.

### SUMMARY

Embodiments of the inventive concepts provide a support unit which improves efficiency of a substrate treating process and a substrate treating apparatus including the same.

In addition, embodiments of the inventive concepts provide a support unit which is capable of protecting a liner from heat generated during a substrate treating process and a substrate treating apparatus including the same.

In addition, embodiments of the inventive concepts provide a support unit which is capable of protecting the support unit from heat generated during a substrate treating process and a substrate treating apparatus including the same.

Embodiments of the inventive concepts provide an apparatus for treating a substrate.

One aspect of embodiments of the inventive concept is directed to provide a substrate treating apparatus including a process chamber having a treating space therein, a support unit placed in the process chamber and supporting a substrate, a gas supply unit supplying a treating gas into the process chamber, a plasma source generating plasma using the treating gas, and a liner unit adjacent to or being in contact with an inner side wall of the process chamber or the support unit in the process chamber. The support unit includes an upper plate on which the substrate is placed, a top surface of the upper plate being formed of a non-conduction material, an electrode plate placed below the upper plate and formed of a conduction material, and a lower plate placed below the electrode plate and having a ring shape. A cooling member is provided in the lower plate.

The cooling member may include a lower flow path which is formed in the lower plate and through which a cooling fluid flows.

The electrode plate may include an upper flow path therein, the upper flow path cooling the upper plate flowing through the upper flow path.

The substrate treating apparatus may further include a heater heating a wall of the process chamber.

The upper plate may include an electrostatic electrode therein, the electrostatic electrode absorbing the substrate using an electrostatic force.

The liner unit may include an inner side liner formed to surround one, a part or all of the upper plate, the electrode plate, and the lower plate, and an outer side liner placed in the process chamber and formed in a ring shape.

Another aspect of embodiments of the inventive concept is directed to provide a support unit for supporting a substrate, the support unit including an upper plate on which a substrate is placed, a top surface of the upper plate being formed of a non-conduction material, an electrode plate placed below the upper plate and formed of a conduction material, and a lower plate placed below the electrode plate and having a ring shape. A cooling member is formed in the lower plate.

The cooling member may include a lower flow path formed in the lower plate and through which a cooling fluid flows, and an upper flow path through which a cooling fluid for cooling the upper plate flows may be included in the electrode plate.

An electrostatic electrode for absorbing a substrate using an electrostatic force may be formed in the upper plate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view illustrating a substrate treating apparatus according to an embodiment of the inventive concept;

FIG. 2 is a diagram illustrating a support unit in FIG. 1;

FIG. 3 is a perspective view illustrating a lower plate in FIG. 2; and

FIG. 4 is a diagram schematically illustrating a heat generation part and a part cooled by a cooling flow path while the process is performed using the substrate treating apparatus in FIG. 1.

### DETAILED DESCRIPTION

Embodiments will be described in detail with reference to the accompanying drawings. The inventive concept, however, may be embodied in various different forms, and should not be construed as being limited only to the illustrated embodiments. Embodiments of the inventive concept are provided to illustrate more fully the scope of the inventive concept to those skilled in the art. Therefore, the shapes of the parts in the drawings may be exaggerated to emphasize a more clear description.

An embodiment of the present invention will be described with respect to a substrate treating apparatus for etching a substrate using the plasma. However, the inventive concept is not limited to this, and plasma is supplied in the process chamber. The inventive concept may be applied to various types of apparatus for performing the process.

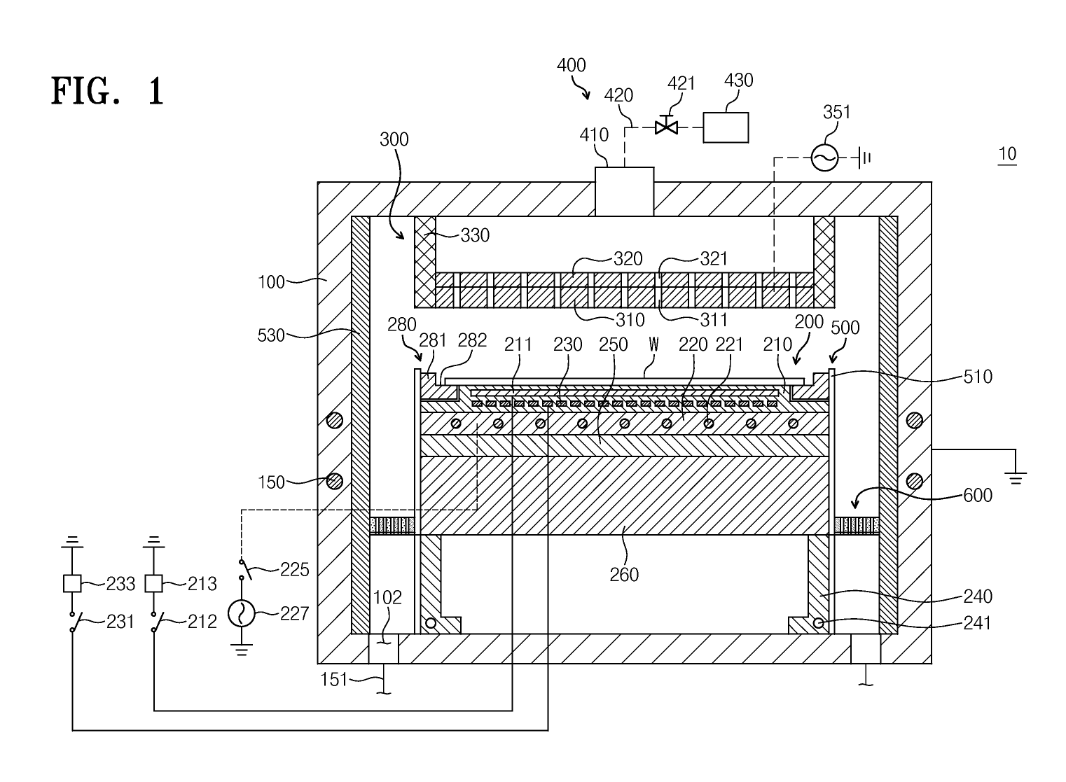

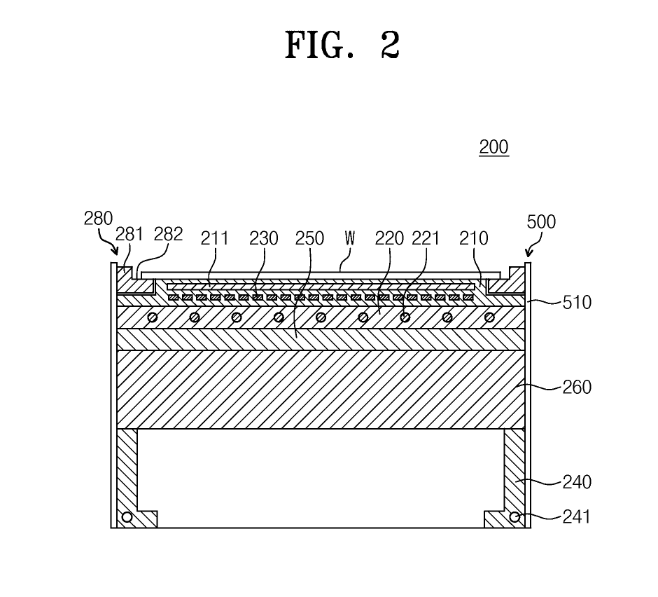

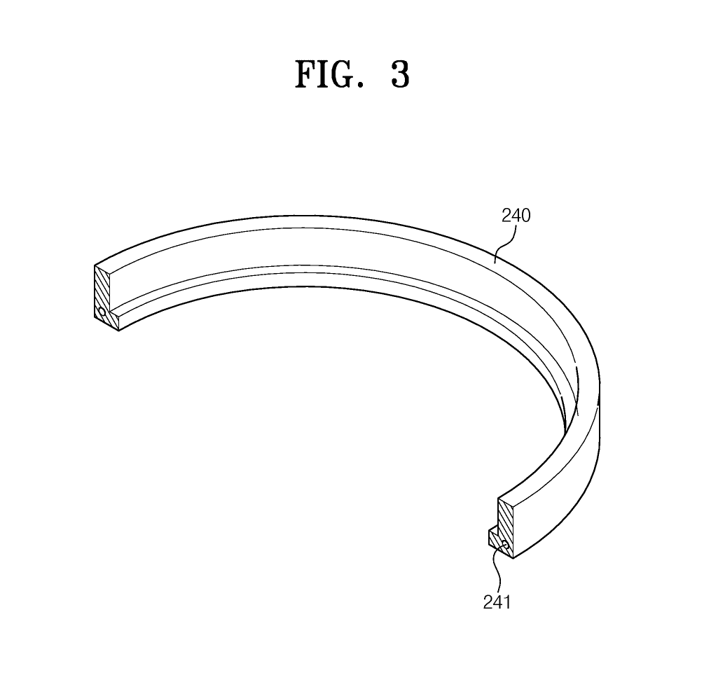

FIG. 1 is a cross-sectional view illustrating a substrate treating apparatus according to an embodiment of the inventive concept. FIG. 2 is a diagram illustrating a support unit in FIG. 1. FIG. 3 is a perspective view illustrating a lower plate in FIG. 2.

Referring to FIGS. 1 to 3, a substrate treating apparatus 10 may treat a substrate W using plasma. The substrate treating apparatus 10 may include a process chamber 100, a support unit 200, a shower head unit 300, a gas supply unit 400, a plasma source unit, a liner unit 500, and a baffle unit 600.

The process chamber 100 may have a treating space where a substrate treating process is performed. The process chamber 100 may have an inner treating space. The process chamber 100 may be provided in such a way that it can be sealed. The process chamber 100 may be formed of a metallic material. In an exemplary embodiment, the process chamber 100 may be formed of an aluminum material. The process chamber 100 may be grounded. A discharge hole 102 may be formed through a bottom surface of the process chamber 100. The discharge hole 102 may be connected to a discharge line 151. A reaction by-product generated during a process and gas remaining in an inner space of the process chamber may be discharged into the outside via the discharge line 151. An inner pressure of the process chamber 100 may be reduced by an exhaust process to a predetermined pressure.

A heater 150 may be provided in a wall of the process chamber 100. The heater 150 may heat the wall of the process chamber 100. The heater 150 may be electrically connected to a heating power (not illustrated). The heater 150 may generate heat using a current supplied from the heating power (not illustrated). The heat generated from the heater 150 may be transmitted into the inner space. The heat generated from the heater 150 may allow the treating space to have a predetermined temperature. The heater 150 may have a coil-like heating wire. The heater 150 may be provided in plural in the wall of the process chamber 100.

The support unit 200 may be placed in the process chamber 100. The support unit 200 may support a substrate W. The support unit 200 may include an electrostatic chuck for absorbing the substrate W using an electrostatic force. On the other hand, the support unit 200 may support the substrate W using a variety of manners such as mechanical clamping and the like. Below, the support unit 200 will be described as being the electrostatic chuck.

The support unit 200 may include an upper plate 210, an electrode plate 220, a heater 230, a lower plate 240, a plate 250, a lower board 260, and a focus ring 280.

The substrate W may be placed on the upper plate 210. The upper plate 210 may be formed in a disk shape. The upper plate 210 may be formed of a dielectric substance. A top surface of the upper plate 210 may have a smaller radius than the substrate W. For this reason, when the substrate W is placed on the upper plate 210, an edge region of the substrate W may be positioned outside the upper plate 210.

An electrostatic force may act between the upper plate 210 and the substrate W when an external power is supplied to the upper plate 210. An electrostatic electrode 211 may be provided in the upper plate 210. An electrostatic chuck 221 may be electrically connected to an absorption power supply 213. The absorption power supply 213 may include a DC power. A switch 212 may be installed between the electrostatic electrode 211 and the absorption power supply 213. The electrostatic electrode 211 may be electrically connected to the absorption power supply 213 by the ON/OFF of the switch 212. When the switch 212 is turned on, a direct current may be applied to the electrostatic electrode 211. The electrostatic force may act between the electrostatic electrode 211 and the substrate W by the current supplied to the electrostatic electrode 211, and thus the substrate W may be absorbed on the upper plate 210 by the electrostatic force.

The heater 230 may be provided in the upper plate 210. The heater 230 may be electrically connected to a heating power 233. The heater 230 may generate heat by resisting a current supplied from the heating power 233. The generated heat may be transmitted to the substrate W via the upper plate 210. The substrate W may maintain a predetermined temperature by the heat generated from the heater 230. The heater 230 may have a coil-like heating wire. The heater 230 may be provided in plural in a region of the upper plate 210.

The electrode plate 220 may be provided below the upper plate 210. The electrode plate 220 may be formed in a disk shape. The electrode plate 220 may be formed of a conduction material. In an exemplary embodiment, the electrode plate 220 may be formed of an aluminum material. An area of a top surface of the electrode plate 220 may correspond to that of a bottom surface of the upper plate 210.

An upper flow path 221 may be provided in the upper plate 220. The upper flow path 221 may mainly cool the upper plate 210. A cooling fluid may be provided in the upper flow path 221. In an exemplary embodiment, the cooling fluid may be cooling water or a cooling gas.

The electrode plate 220 may include a metal plate. In an exemplary embodiment, the whole of the electrode plate 220 may be formed of the metal plate. The electrode plate 220 may be electrically connected to a lower power supply 227. The lower power supply 227 may be a high-frequency power supply for generating a high-frequency power. The high-frequency power may be an RF power. The RF power may be a high bias RF power. The high-frequency power may be supplied to the electrode plate 220 from the lower power supply 227, and thus the electrode plate 220 may function as an electrode. The electrode plate 220 may be grounded.

The plate 250 may be formed below the upper plate 220. The plate 250 may be formed in the shape of a disk plate. An area of the plate 250 may correspond to that of the electrode plate 220. The plate 250 may include an insulation plate. In an exemplary embodiment, the plate 250 may be formed of a dielectric substance.

The lower plate 240 may be provided below the electrode plate 220. The lower plate 240 may be formed below the lower board 260. The lower plate 240 may be provided in the shape of a ring. A lower flow path 241 which is a cooling flow path may be provided in the lower plate 240.

The lower flow path 241 may receive a cooling fluid and may lower temperature in the process chamber 100 heated during a process. The lower flow path 241 may cool an inner side liner 510 adjacent thereto. The lower flow path 241 may be formed in the lower plate 240 in the shape of a ring.

The lower board 260 may be placed below the plate 250. The lower board 260 may be formed of an aluminum material. The lower board 260 may be formed in a circular shape when viewed from the top. A lift pin module (not illustrated) which moves the substrate W from an external transfer member to the upper plate 210 and the like may be placed in an inner space of the lower board 260.

The focus ring 280 may be arranged at an edge region of the support unit 200. The focus ring 280 may have a ring shape. The focus ring 280 may be provided to surround an upper portion of the upper plate 210. The focus ring 280 may include an inner side part 282 and an outer side part 281. The inner side part 282 may be placed at the inside of the focus ring 280. The inner side part 282 may be formed to be lower than the outer side part 281. A top surface of the inner side part 282 and a top surface of the upper plate 210 may be the same in height. The inner side part 282 may support the edge region of the substrate W which is placed outside the support plate 210. The outer side part 281 may be placed at the outside of the inner side part 282. The outer side part 281 may be disposed to face a side portion of the substrate when the substrate is placed on the support plate 210. The outer side part 281 may be formed to surround the edge region of the substrate W.

A shower head unit 300 may be placed above the support unit 200 in the process chamber 100. The shower head unit 300 may be arranged to face the support unit 200.

The shower head unit 300 may include a shower head 310, a gas discharge plate 320, and a supporting unit 330. The shower head 310 may be spaced apart by a constant distance from a top end portion of the process chamber 100 toward the bottom thereof. A constant space may be formed between the gas discharge plate 320 and the top surface of the process chamber 100. The shower head 310 may be formed in the shape of a plate having a constant thickness. A bottom surface of the shower head 310 may be anodized to prevent an arc from occurring due to the plasma. A shape and an area of a cross section of the shower head 310 may be the same as those of the support unit 200. The shower head 310 may include a plurality of discharge holes 311. The discharge holes 311 may pass through top and bottom surfaces of the shower head 310 in a vertical direction. The shower head 310 may be formed of a metallic material.

The gas discharge plate 320 may be placed on the top surface of the shower head 310. The gas discharge plate 320 may be spaced apart by a constant distance from the top surface of the process chamber 100. The gas discharge plate 320 may be formed in the shape of a plate having a constant thickness. The discharge holes 321 may be provided in the gas discharge plate 320. The discharge holes 321 may pass through top and bottom surfaces of the shower head 320 in a vertical direction. The discharge holes 321 may be placed to face discharge holes 311 of the shower head 310. The gas discharge plate 320 may have a metallic material.

The shower head 310 may be electrically connected to an upper power supply 351. The upper power supply 351 may be a high-frequency power supply. In contrast, the shower head 310 may be electrically grounded. The shower head 310 may be electrically connected to the upper power supply 351. In contrast, the shower head 310 may be electrically grounded and may function as an electrode.

The supporting unit 330 may support side portions of the shower head 310 and the gas discharge plate 320. A top end of the supporting unit 330 may be connected to a top surface of the process chamber 100, and a bottom end portion of the supporting unit 330 may be connected to side portions of the shower head 310 and the gas discharge plate 320. The supporting unit 330 may be formed of a non-metallic material.

A gas supply unit 400 may supply a process gas into the process chamber 100. The gas supply unit 400 may include a gas supply nozzle 410, a gas supply line 420, and a gas storage unit 430. The gas supply nozzle 410 may be installed at a center portion of the top surface of the process chamber 100. A discharge hole may be formed at a bottom surface of the gas supply nozzle 410. The discharge hole may supply the process gas into the process chamber 100. The gas supply line 420 may connect the gas supply nozzle 410 to the gas storage unit 430. The gas supply line 420 may supply the process gas, stored in the gas storage unit 430, into the gas supply nozzle 410. A valve 421 may be installed at the gas supply line 420. The valve 421 may open and close the gas supply line 420 and may adjust a flow rate (e.g., quantity of flow) of the process gas flowing through the gas supply line 420.

A plasma source may excite the process gas into a plasma state in the process chamber 100. In an exemplary embodiment of the inventive concept, a capacitively coupled plasma (CCP) apparatus may be used as the plasma source. The capacitively coupled plasma (CCP) apparatus may include an upper electrode and a lower electrode in the process chamber 100. The upper electrode and the lower electrode may be arranged vertically in parallel to each other in the process chamber 100. A high-frequency power may be supplied to one of both electrodes, and the other thereof may be grounded. An electromagnetic field may be formed at a space between both electrodes, and a process gas supplied to the space may be excited into a plasma state. The substrate treating process may be performed using the plasma. In an exemplary embodiment, an upper electrode may be provided with the shower head unit 300, and a lower electrode may be provided with an electrode plate. The high-frequency power may be supplied to the lower electrode, and the upper electrode may be grounded. In contrast, the high-frequency power may be supplied to both the upper electrode and the lower electrode. Accordingly, the electromagnetic field may be generated between the upper electrode and the lower electrode. The generated electromagnetic field may excite the process gas provided in the process chamber 100 into the plasma state.

The liner unit 500 may prevent an inner wall of the process chamber 100 and the support unit 200 from being damaged during the process. The liner unit 500 may prevent impurities occurring during the process from being deposited on the inner side wall of the process chamber 100 and the support unit 200. The liner unit 500 may include an inner side liner 510 and an outer side liner 530 in the processor chamber.

The outer side liner 530 may be formed on an inner side wall of the process chamber 100. The outer side liner 530 may have a space where top and bottom surfaces thereof are opened. The outer side liner 530 may be formed in a cylinder shape. A radius of the outer side liner 530 may correspond to that of a space defined by the inner side surface of the process chamber 100. The outer side liner 530 may be formed along the inner surface of the process chamber 100.

The outer side liner 530 may be formed of an aluminum material. The outer side liner 530 may protect an inner surface of the process chamber 100. An arc discharge may occur in the process chamber 100 while the process gas is excited. The arc discharge may damage the process chamber 100. The outer side liner 530 may protect the inner surface of the process chamber 100, thereby preventing the inner surface of the process chamber 100from being damaged by the arc discharge.

The inner side liner 510 may be formed to surround the support unit 200. The inner side liner 510 may be provided in a ring shape. The inner side liner 510 may be formed to surround all of the upper plate 210, the electrode plate 220, and the lower plate 240. In contrast, the inner side liner 510 may be formed to surround one, a part or all of the upper plate 210, the electrode plate 220, and the lower plate 240. The inner side liner 510 may be formed of an aluminum material. The inner side liner 510 may protect an outer surface of the support unit 200.

A baffle unit 600 may be placed between the inner side wall of the process chamber 100 and the support unit 200. The baffle unit 600 may be formed in an annular ring shape. A plurality of through-holes may be formed in the baffle unit 600. The process gas provided in the process chamber 100 may be discharged into the discharge hole 102 through the through-holes of the baffle unit 600. The flow of the process gas may be adjusted according to shapes of the baffle unit 600 and the through-holes shape.

The substrate treating apparatus according to an exemplary embodiment of the inventive concept is described as being a capacitively coupled plasma (CCP) apparatus. In contrast, an exemplary embodiment of the inventive concept may be applicable to a substrate treating apparatus using plasma such as an inductively coupled plasma (ICP) apparatus and the like.

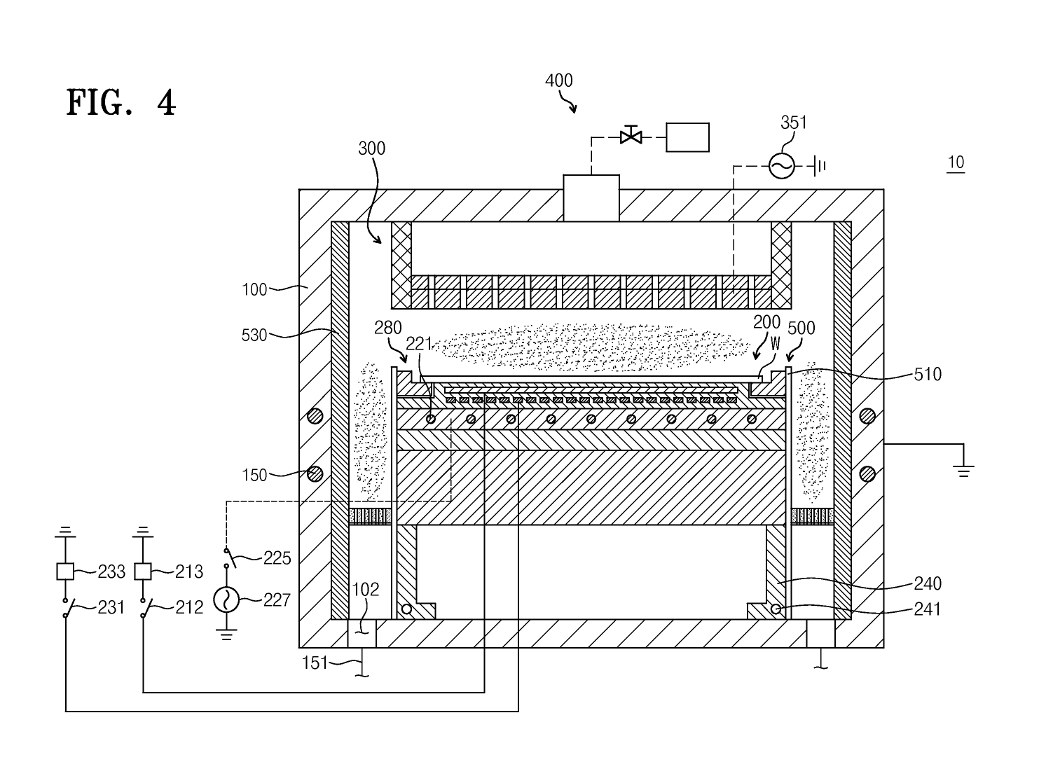

FIG. 4 is a diagram schematically illustrating a heat generation part and a part cooled by a cooling flow path while the process is performed using the substrate treating apparatus in FIG. 1. Referring to FIG. 4, plasma provided during a substrate treating process may pass through a top surface of a substrate and a space defined by the support unit 200 and the process chamber 100. The plasma may be a high-temperature material. Temperature may increase around a region where the plasma remains. The temperature may increase on the upper plate 210, an outer surface of the support unit 200, and the inner side wall of the process chamber 100. Although the liner unit 500 is around the inner side wall of the process chamber 100 and the support unit 200, the temperature may also increase at the liner unit 500 due to the plasma.

However, the increased temperature in the process chamber 100 may decrease through the upper flow path 221 and the lower flow path 241 provided in the support unit 200. Cooling using the upper flow path 221 and the lower flow path 241 may lower the temperature in the process chamber 100. In addition, the liner unit 500 and parts of the support unit 200 may be protected from heat damage.

According to an exemplary embodiment of the inventive concept, a cooling flow path may be provided at a lower portion of a support unit, thereby improving efficiency of a substrate treating process.

Furthermore, according to an exemplary embodiment of the inventive concept, a cooling flow path may be provided at a lower portion of a support unit, thereby preventing parts in a substrate treating apparatus from being damaged during a process.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A substrate treating apparatus comprising:
a process chamber having a treating space therein;
a support unit placed in the process chamber and supporting a substrate;
a gas supply unit supplying a treating gas into the process chamber;
a plasma source generating plasma using the treating gas; and
a liner unit adjacent to or being in contact with an inner side wall of the process chamber or the support unit in the process chamber,
wherein the support unit comprises:
an upper plate on which the substrate is placed, a top surface of the upper plate being formed of a non-conduction material;
an electrode plate placed below the upper plate and formed of a conduction material; and
a lower plate placed below the electrode plate and having a ring shape, and
wherein a cooling member is provided in the lower plate.

2. The substrate treating apparatus of claim 1, wherein the cooling member comprises a lower flow path which is formed in the lower plate and through which a cooling fluid flows.

3. The substrate treating apparatus of claim 2, wherein the electrode plate comprises an upper flow path therein, the upper flow path cooling the upper plate flowing through the upper flow path.

4. The substrate treating apparatus of claim 3, further comprising:
a heater heating a wall of the process chamber.

5. The substrate treating apparatus of claim 4, wherein the upper plate comprises an electrostatic electrode therein, the electrostatic electrode absorbing the substrate using an electrostatic force.

6. The substrate treating apparatus of claim 4, wherein the liner unit comprises:
an inner side liner formed to surround one, a part or all of the upper plate, the electrode plate, and the lower plate; and
an outer side liner placed in the process chamber and formed in a ring shape.

7. A support unit for supporting a substrate, the support unit comprising:
an upper plate on which a substrate is placed, a top surface of the upper plate being formed of a non-conduction material;
an electrode plate placed below the upper plate and formed of a conduction material; and
a lower plate placed below the electrode plate and having a ring shape,
wherein a cooling member is formed in the lower plate.

8. The support unit of claim 7, wherein the cooling member comprises:
a lower flow path formed in the lower plate and through which a cooling fluid flows, and
wherein an upper flow path through which a cooling fluid for cooling the upper plate flows is included in the electrode plate.

9. The support unit of claim 7, wherein an electrostatic electrode for absorbing a substrate using an electrostatic force is formed in the upper plate.
